(19) United States
(12) Patent Application Publication
(10) Pub. No.: US 2026/0164834 A1
(43) Pub. Date: Jun. 11, 2026

(54) IMAGE SENSOR

(71) Applicant: Samsung Electronics Co., Ltd., Suwon-si (KR)

(72) Inventors: Seungho LEE, Suwon-si (KR); Jungsan KIM, Suwon-si (KR); Taemin KIM, Suwon-si (KR); Yongsoon PARK, Suwon-si (KR)

(21) Appl. No.: 19/295,793

(22) Filed: Aug. 11, 2025

(30) Foreign Application Priority Data
Dec. 9, 2024 (KR) 10-2024-0181877

(51) Int. Cl. H10F 39/00; G01J 1/44; G01J 1/46; H01L 23/522; H04N 25/616; H04N 25/771; H10F 39/18

(52) U.S. Cl. CPC H10F 39/811; G01J 1/46; H10F 39/182; H10W 20/496; G01J 2001/446; H04N 25/616; H04N 25/771

(57) ABSTRACT

An image sensor may include a substrate including a photodiode, a first capacitor and a second capacitor provided on the substrate and spaced apart from each other in a first direction parallel to a top surface of the substrate, and a first via extending lengthwise in a vertical direction disposed between the first and second capacitors. The first capacitor may include a first electrode, a second electrode and a first dielectric layer interposed between the first and second electrodes. The second capacitor may include a third electrode, a fourth electrode and a second dielectric layer interposed between the third and fourth electrodes. The first via may be electrically connected to the first and third electrodes.

### CROSS-REFERENCE TO RELATED APPLICATIONS

This U.S. non-provisional patent application claims priority under 35 U.S.C. § 119 to Korean Patent Application No. 10-2024-0181877, filed on Dec. 9, 2024, in the Korean Intellectual Property Office, the entire contents of which are hereby incorporated by reference.

### BACKGROUND OF THE INVENTION

The present disclosure relates to an image sensor such as an image sensor including a plurality of stacked capacitors.

An image sensor is a semiconductor device for converting an optical image to electric signals. Image sensors may be classified into two types: a charge coupled device (CCD) type and a complementary metal-oxide-semiconductor (CMOS) type. In general, the CMOS-type image sensor may be referred to as a “CIS”. The CIS includes a plurality of pixels that are two-dimensionally arranged. Each of the pixels includes a photodiode (PD). The photodiode converts an incident light to an electric signal.

### SUMMARY

An embodiment of the inventive concept provides an image sensor with improved electrical characteristics.

According to an embodiment of the inventive concept, an image sensor may include a substrate including a photodiode, a first capacitor and a second capacitor provided on the substrate and spaced apart from each other in a first direction parallel to a top surface of the substrate, and a first via extending lengthwise in a vertical direction disposed between the first and second capacitors. The first capacitor may include a first electrode, a second electrode and a first dielectric layer interposed between the first and second electrodes. The second capacitor may include a third electrode, a fourth electrode and a second dielectric layer interposed between the third and fourth electrodes. The first via may be electrically connected to the first and third electrodes.

According to an embodiment of the inventive concept, an image sensor may include a substrate including a photodiode, a first capacitor and a second capacitor provided on the substrate and spaced apart from each other in a first direction parallel to a top surface of the substrate, a first via extending lengthwise in a vertical direction and disposed between the first and second capacitors, a second via vertically overlapping with the first capacitor, and a third via vertically overlapping with the second capacitor. The first capacitor includes a first stack of electrodes and dielectric layers alternately stacked with the electrodes. The second capacitor comprises a second stack of electrodes and dielectric layers alternately stacked with the second electrodes. The first via may be electrically connected to a first electrode of the first capacitor and third electrode of the second capacitor. The second via may be electrically connected to a second electrode of the first capacitor that is not electrically connected to the first via. The third via may be electrically connected to a fourth electrode of the second capacitor that is not electrically connected to the first via.

According to an embodiment of the inventive concept, an image sensor may include a substrate including a photodiode and having a first surface and a second surface, which are opposite to each other in a vertical direction, a first capacitor and a second capacitor provided on the first surface of the substrate and spaced apart from each other in a first horizontal direction, a first via disposed between the first and second capacitors, a second via vertically overlapping with the first capacitor, and a third via vertically overlapping with the second capacitor. The first capacitor may include first and second electrodes, which are alternately stacked on top of each other in the vertical direction, and a first dielectric layer, which is interposed between the first and second electrodes. The second capacitor may include third and fourth electrodes, which are alternately stacked on top of each other in the vertical direction, and a second dielectric layer, which is interposed between the third and fourth electrodes. The first via may be electrically connected to the first electrode and the third electrode, and the second via may be electrically connected to the second electrode. The third via may be electrically connected to the fourth electrode, and the first and third electrodes constitute a first plate.

### BRIEF DESCRIPTION OF THE DRAWINGS

FIG. 1 is a block diagram illustrating an image processing device according to an embodiment of the inventive concept.

FIG. 2 is a circuit diagram of an image sensor according to an embodiment of the inventive concept.

FIG. 3 is a plan view illustrating a single pixel region of an image sensor, according to an embodiment of the inventive concept.

FIG. 4 is a plan view illustrating a portion of a capacitor according to an embodiment of the inventive concept.

FIG. 5 is a plan view illustrating a portion of a capacitor according to an embodiment of the inventive concept.

FIG. 6 is a sectional view taken along line A-A′ of FIG. 3.

FIG. 7 is a sectional view taken along line B-B′ of FIG. 3.

FIG. 8 is a sectional view taken along line C-C′ of FIG. 3.

FIGS. 9, 10, 11, 12, 13, 14, 15, and 16 are sectional views illustrating a process of fabricating an image sensor according to an embodiment of the inventive concept.

### DETAILED DESCRIPTION

Example embodiments of the inventive concepts will now be described more fully with reference to the accompanying drawings, in which example embodiments are shown. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail.

Throughout the specification, when a component is described as “including” a particular element or group of elements, it is to be understood that the component may be formed of only the element or the group of elements, or the element or group of elements may be combined with additional elements to form the component, unless the context indicates otherwise. The term “consisting of,” on the other hand, indicates that a component is formed only of the element(s) listed.

Hereinafter, embodiments in the example embodiment will be described as follows with reference to the accompanying drawings. Items described in the singular herein may be provided in plural, as can be seen, for example, in the drawings. Thus, the description of a single item that is provided in plural should be understood to be applicable to the remaining plurality of items unless context indicates otherwise.

It will be understood that when an element is referred to as being “on” another element, it can be directly on the other element or intervening elements may be present. Additionally, in the present specification, the terms ‘connection’ or ‘connected’ may refer to either a physical or an electrical connection between elements that are in physical contact with each other or electrically coupled to each other. An electrical connection refers to a conductive connection in which an electrical signal can be transferred from one component to the other (although such electrical signal may be attenuated in strength as it is transferred and may be selectively transferred).

Ordinal numbers such as “first,” “second,” “third,” etc., may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be referenced elsewhere with a different ordinal number (e.g., “second” in the specification or another claim).

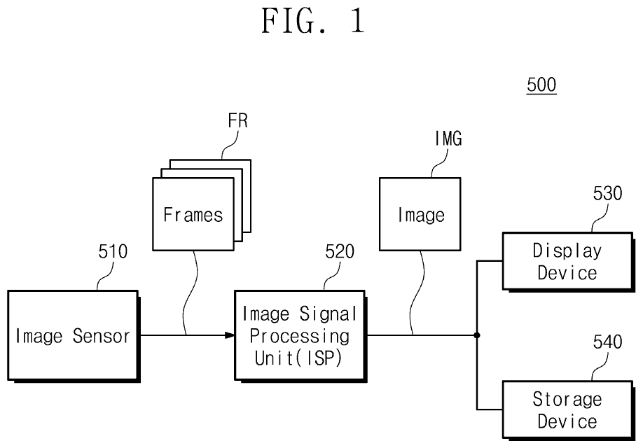

FIG. 1 is a block diagram illustrating an image processing device according to an embodiment of the inventive concept.

Referring to FIG. 1, an image processing device 500 according to an embodiment of the inventive concept may include an image sensor 510, an image signal processing unit (ISP) 520, a display device 530, and a storage device 540.

The image processing device 500 may be included in an electronic device (e.g., smart phones and digital cameras) that is configured to obtain an image of an external object.

The image sensor 510 may be configured to convert an image, which is obtained from an external object, to electric signals or data signals. The image sensor 510 may include a plurality of pixel regions. Each of the pixel regions may be configured to receive light reflected from an external object and convert the received light to electrical signals (e.g., video signals or picture signals).

The image signal processing unit 520 may be configured to perform a signal processing operation on frame data FR (e.g., video data or picture data), which are received from the image sensor 510, and to output image data IMG, which are based on the frame data and corrected through the signal processing operation. For example, the image signal processing unit 520 may perform a signal processing operation (e.g., color interpolation, color correction, gamma correction, color space conversion, and edge correction) on the received frame data FR to generate the image data IMG.

The display device 530 may be configured to output the image data IMG, which is provided from the image signal processing unit 520, to a user. For example, the display device 530 may include at least one of various display panels (e.g., a liquid crystal display panel, an organic light emitting display panel, an electrophoretic display panel, and an electrowetting display panel). The display device 530 may output the image data IMG through the display panel.

The storage device 540 may store the image data IMG from the image signal processing unit 520. The storage device 540 may include a volatile memory device (e.g., a static random access memory (SRAM) device, a dynamic RAM (DRAM) device, or a synchronous DRAM (SDRAM) device) or a nonvolatile memory device (e.g., a read only memory (ROM) device, a programmable ROM (PROM) device, an electrically programmable ROM (EPROM) device, an electrically erasable and programmable ROM (EEPROM) device, a FLASH memory device, a phase-change RAM (PRAM) device, a magnetic RAM (MRAM) device, a resistive RAM (RRAM) device, or a ferroelectric RAM (FRAM) device).

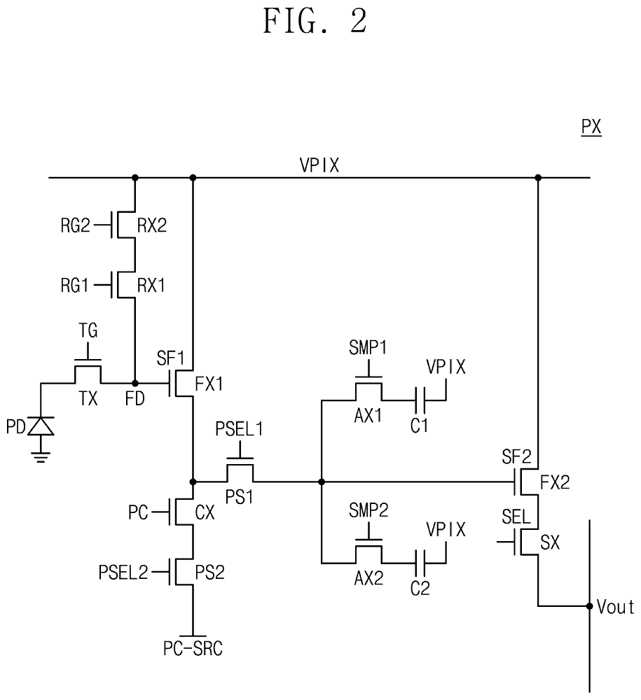

The image sensor 510 according to an embodiment of the inventive concept may include capacitors, which are used as storage elements for storing electric charges (i.e., electrical signals) generated from a photoelectric conversion part, as will be described below. FIG. 2 illustrates an example of the circuit diagram of the image sensor 510, but the inventive concept is not limited to this example and may be applied to any image sensor with a capacitor.

FIG. 2 is a circuit diagram of an image sensor according to an embodiment of the inventive concept.

Referring to FIG. 2, an image sensor may have an in-pixel correlated double sampling (CDS) structure.

In detail, each of pixel regions PX of the image sensor may include a photoelectric conversion part PD, a transfer transistor TX including a transfer gate TG, a first reset transistor RX1 including a first reset gate RG1, a second reset transistor RX2 including a second reset gate RG2, a first source follower transistor FX1 including a first source follower gate SF1, a pre-charge transistor CX including a pre-charge gate PC, a first pre-charge selection transistor PS1 including a first pre-charge selection gate PSEL1, a second pre-charge selection transistor PS2 including a second pre-charge selection gate PSEL2, a first sampling transistor AX1 including a first sampling gate SAM1, a second sampling transistor AX2 including a second sampling gate SAM2, a second source follower transistor FX2 including a second source follower gate SF2, a selection transistor SX including a selection gate SEL, a first capacitor C1, and a second capacitor C2.

The photoelectric conversion part PD may be a photodiode. A first terminal of the transfer transistor TX may be connected to the photoelectric conversion part PD. A second terminal of the transfer transistor TX may correspond to a floating diffusion region FD. The floating diffusion region FD may be connected to a first terminal of the first reset transistor RX1. The floating diffusion region FD may be connected to the first source follower gate SF1 of the first source follower transistor FX1.

A first terminal of the first source follower transistor FX1 may be connected to the pre-charge transistor CX and the first pre-charge selection transistor PS1. A first terminal of the pre-charge transistor CX may be connected to the second pre-charge selection transistor PS2. A first terminal of the second pre-charge selection transistor PS2 may be connected to a pre-charge source line PC-SRC.

A first terminal of the first pre-charge selection transistor PS1 may be connected to a first terminal of the first sampling transistor AX1 and a first terminal of the second sampling transistor AX2. The first capacitor C1 may be connected to a second terminal of the first sampling transistor AX1. The second capacitor C2 may be connected to a second terminal of the second sampling transistor AX2.

A power voltage VPIX may be applied to a second terminal of the second reset transistor RX2, a second terminal of the first source follower transistor FX1, the first capacitor C1, the second capacitor C2, and a first terminal of the second source follower transistor FX2. For example, the first capacitor C1 may be placed between and connected to the second terminal of the first sampling transistor AX1 and the power voltage VPIX. The second capacitor C2 may be placed between and connected to the second terminal of the second sampling transistor AX2 and the power voltage VPIX. A first terminal of the selection transistor SX may be connected to an output line Vout.

An operation of the image sensor of FIG. 2 may include a step of sampling a reset value and a step of sampling a signal value. Before a photon accumulation step, the photoelectric conversion part PD may be reset through the floating diffusion region FD. After the reset of the photoelectric conversion part PD, the photon accumulation (e.g., frame capture) step may be started. This may induce a noise component in the reset value. The reset value containing the noise component may be stored in the first capacitor C1 through the first sampling transistor AX1.

Before the sampling step begins, the first and second capacitors C1 and C2 may undergo a pre-charge operation to remove a previously-sampled voltage, allowing the first and second source follower transistors SF1 and SF2 to sample a new voltage. The pre-charge operation may be performed using the pre-charge transistor CX and the first and second pre-charge selection transistors PSEL1 and PSEL2.

After the sampling step, electric charges may be transferred from the photoelectric conversion part PD to the floating diffusion region FD, and thus, the floating diffusion region FD may have a new voltage (i.e., a new signal value). The signal value of the floating diffusion region FD may be sampled to the second capacitor C2 through the second sampling transistor AX2. A signal value, from which a noise component is removed, may be accurately obtained by subtracting a reset value stored in the first capacitor C1 from a signal value stored in the second capacitor C2, and in this case, it may be possible to realize a clear image sensor.

According to an embodiment of the inventive concept, the image sensor may be operated in a global shutter mode. In the global shutter mode, electrical signals (i.e., data), which are generated by all of the pixel regions PX in the image sensor, may be sampled/stored in the first and second capacitors C1 and C2, which are provided in each of the pixel regions, simultaneously or respectively, and the data may be sequentially read out in order of row or column by the image signal processing unit 520 of FIG. 1. Accordingly, it may be possible to realize the global shutter mode. The image sensor according to an embodiment of the inventive concept may be called a voltage-type global shutter image sensor. At least one transfer transistor TX may be disposed in each of the pixel regions PX. In an embodiment, all or at least one of the remaining transistors may be disposed in each of the pixel region PX and may be shared by adjacent ones of the pixel regions PX.

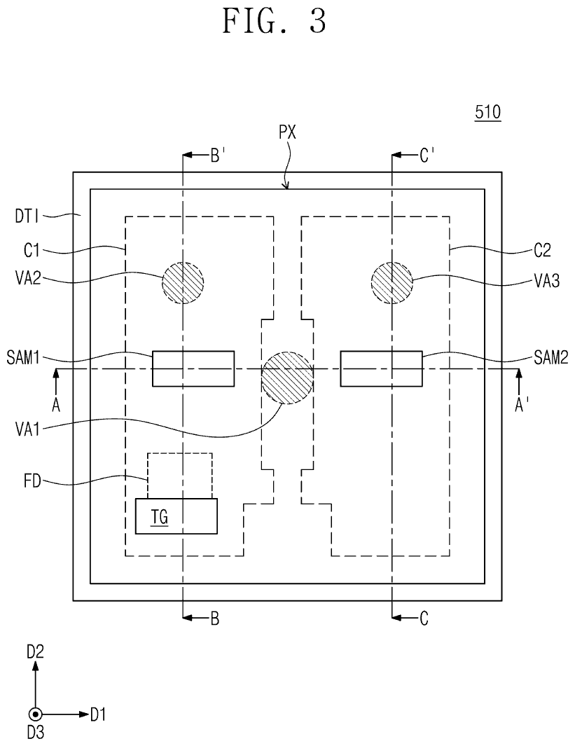

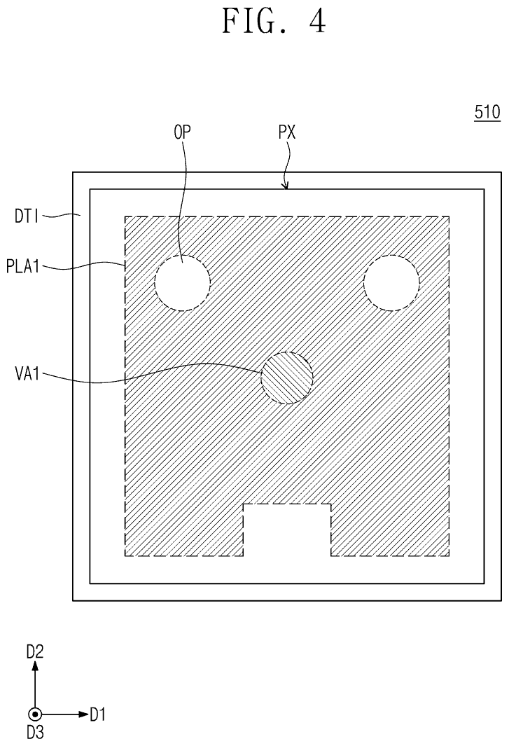

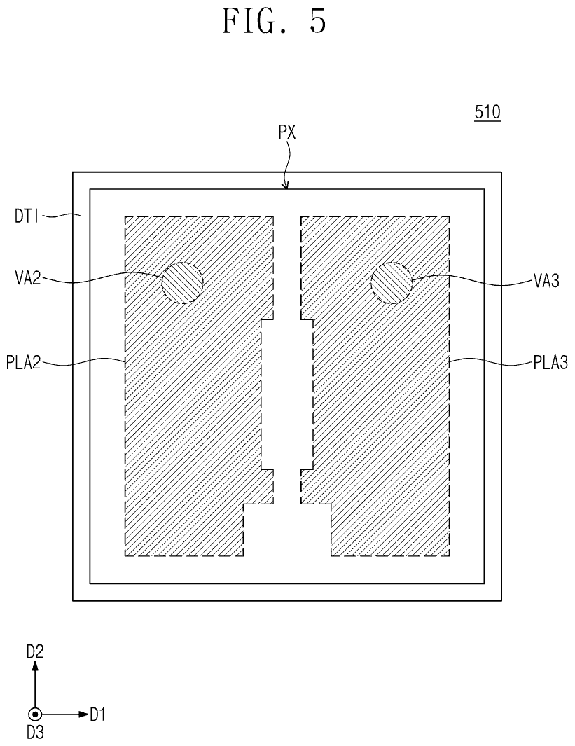

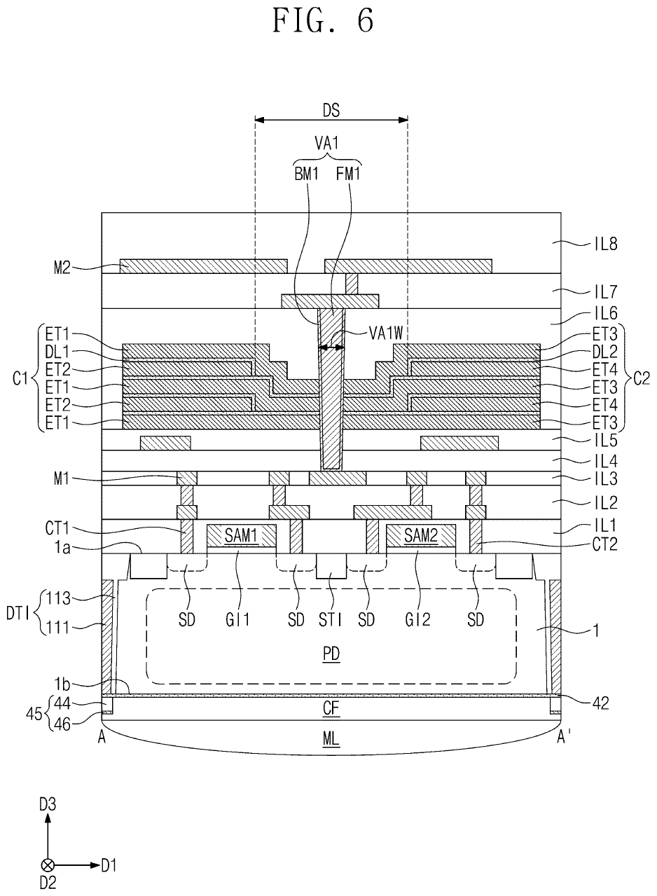

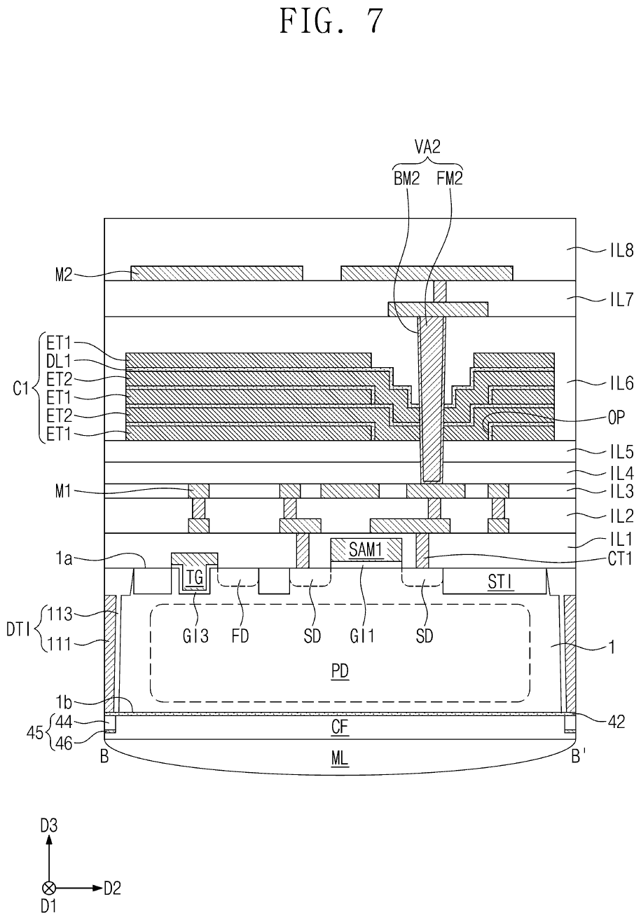

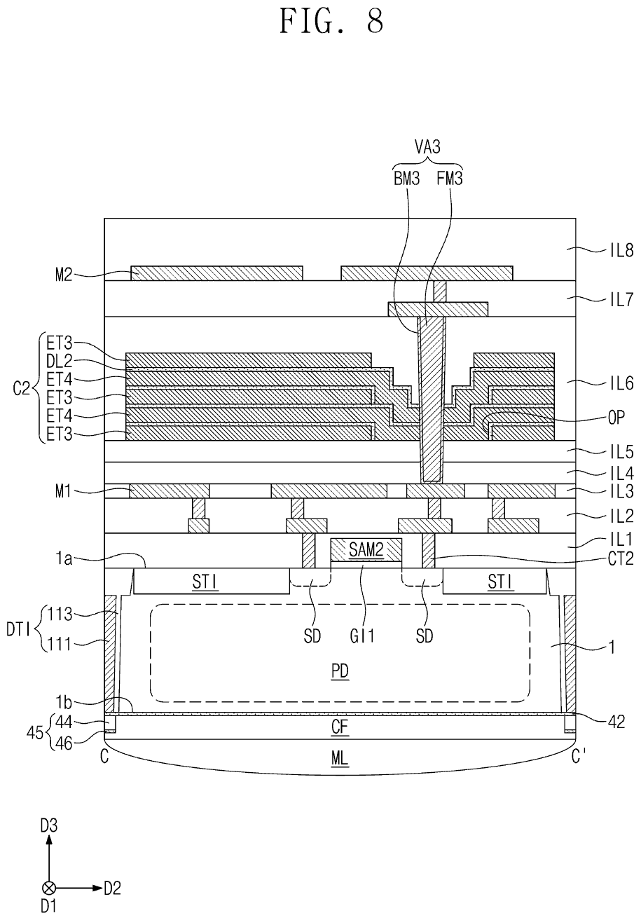

FIG. 3 is a plan view illustrating a single pixel region of an image sensor, according to an embodiment of the inventive concept. FIG. 4 is a plan view illustrating a portion of a capacitor according to an embodiment of the inventive concept. FIG. 5 is a plan view illustrating a portion of a capacitor according to an embodiment of the inventive concept. FIG. 6 is a sectional view taken along line A-A′ of FIG. 3. FIG. 7 is a sectional view taken along line B-B′ of FIG. 3. FIG. 8 is a sectional view taken along line C-C′ of FIG. 3.

Referring to FIGS. 3 to 8, the image sensor 510 may include a substrate 1. The substrate 1 may have a first surface 1a and a second surface 1b, which are opposite to each other. Light may be incident into the substrate 1 through the second surface 1b. The substrate 1 may be a single crystalline wafer, which is formed of or includes silicon and/or germanium, an epitaxial layer, or a silicon-on-insulator (SOI) wafer.

In the present specification, a first direction D1 may be defined as a direction that is parallel to the first surface 1a of the substrate 1. A second direction D2 may be defined as a direction that is parallel to the first surface 1a of the substrate 1 and is perpendicular to the first direction D1. The first direction D1 and the second direction D2 may be referred to as horizontal directions, wherein horizontal is relative to the first surface 1A of the substrate. A third direction D3 may be defined as a direction that is perpendicular to the first surface 1a of the substrate 1. The third direction D3 may also be referred to as a vertical direction, wherein vertical is relative to the first surface 1a of the substrate. The substrate 1 may be doped with first impurities to have a first conductivity type. The first impurity may be, for example, boron. The first conductivity type may be, for example, a p-type.

The photoelectric conversion part PD may be disposed in the substrate 1. Although not shown, a plurality of photoelectric conversion parts PD may be provided in the image sensor 510, and may be separated from each other by an isolation structure DTI, which will be described below. The photoelectric conversion part PD may be doped with second impurities to have a second conductivity type different from the first conductivity type. The second impurity may be, for example, phosphorus or arsenic. The second conductivity type may be, for example, an n-type. Here, the n-type region of the photoelectric conversion part PD and the p-type region of the substrate 1 adjacent thereto may form a pn junction serving as a photodiode or generating electron-hole pairs when light is incident thereto. The electrons generated by the process may be transferred to the photoelectric conversion part PD.

A device isolation portion STI may be disposed in the substrate 1 to separate electronic devices (e.g., transistors) from each other. The device isolation portion STI may be formed of or include at least one of silicon oxide, silicon nitride, or silicon oxynitride.

The isolation structure DTI may be disposed in the substrate 1 to isolate each of the photoelectric conversion parts PD. The isolation structure DTI may be provided to penetrate the substrate 1. A width of the isolation structure DTI in the first direction D1 may decrease as a distance from the first surface 1a increases in a direction toward the second surface 1b.

The isolation structure DTI may include a first isolation pattern 111 and a second isolation pattern 113. The first isolation pattern 111 may be spaced apart from the substrate 1. The first isolation pattern 111 may include a conductive material having a refractive index different from that of the substrate 1. The first isolation pattern 111 may be formed of or include at least one of doped polysilicon or a metallic material.

The second isolation pattern 113 may be interposed between the first isolation pattern 111 and the substrate 1. The second isolation pattern 113 may include an insulating material having a refractive index different from that of the substrate 1. In an embodiment, the second isolation pattern 113 may be formed of or include silicon oxide.

A negative bias voltage may be applied to the first isolation pattern 111. The first isolation pattern 111 may serve as a common bias line. In this case, it may be possible to immobilize holes, which may be present on a surface of the substrate 1 in contact with the isolation structure DTI, and thereby improve a dark current property of the image sensor.

The visible boundary is illustrated to be formed between the device isolation portion STI and the isolation structure DTI, but in an embodiment, the boundary between the device isolation portion STI and the isolation structure DTI may not be visible or observable. As an example, there may be no interface between the device isolation portion STI and the second isolation pattern 113.

The first sampling gate SAM1 and the second sampling gate SAM2 may be disposed on the first surface 1a of the substrate 1. The first sampling gate SAM1 and the second sampling gate SAM2 may be spaced apart from each other in the first direction D1.

A first gate insulating layer GI1 may be interposed between the first sampling gate SAM1 and the substrate 1. A second gate insulating layer GI2 may be interposed between the second sampling gate SAM2 and the substrate 1. Impurity regions SD may be disposed at both sides of each of the first and second sampling gates SAM1 and SAM2. The impurity regions SD may be provided in the substrate 1. The impurity regions SD may be doped with the second impurities described above. The first sampling gate SAM1 and the impurity regions SD may constitute the first sampling transistor AX1 described with reference to FIG. 2. The second sampling gate SAM2 and the impurity regions SD may constitute the second sampling transistor AX2 described with reference to FIG. 2.

The transfer gate TG may be disposed on the first surface 1a of the substrate 1. In an embodiment, a portion of the transfer gate TG may be provided in the substrate 1. The remaining portion of the transfer gate TG may be provided on the first surface 1a. For example, a portion of the transfer gate TG may be extended into the substrate 1. A third gate insulating layer GI3 may be interposed between the transfer gate TG and the substrate 1.

The floating diffusion region FD may be disposed in the substrate 1 and adjacent to the transfer gate TG. The floating diffusion region FD may be doped with the second impurities to have the second conductivity type. In the case where a voltage is applied to the transfer gate TG, the electrons may be transferred to the floating diffusion region FD. For convenience in illustration, only the transfer gate TG and the first and second sampling gates SAM1 and SAM2 are illustrated in FIGS. 3 to 8, and some of the transistors in FIG. 2 are omitted from FIGS. 3 to 8.

First to eighth interlayer insulating layers IL1 to IL8 may be disposed on the first surface 1a of the substrate 1. The plurality of interlayer insulating layers IL1 to IL8 may be formed of or include at least one of silicon oxide or silicon nitride. In an embodiment, the first to third interlayer insulating layers IL1 to IL3 may be formed of or include silicon oxide. The fourth interlayer insulating layer IL4 may be formed of or include silicon nitride. The fifth to eighth interlayer insulating layers IL5 to IL8 may be formed of or include silicon oxide.

First contact plugs CT1 and second contact plugs CT2 may be provided to penetrate the first interlayer insulating layer IL1. The first contact plugs CT1 may be spaced apart from each other in the first direction D1, with the first sampling gate SAM1 interposed therebetween. The first contact plug CT1 may be connected to at least one of the impurity regions SD, which are formed adjacent to the first sampling gate SAM1. The second contact plugs CT2 may be spaced apart from each other in the first direction D1, with the second sampling gate SAM2 interposed therebetween. The second contact plug CT2 may be connected to at least one of the impurity regions SD, which are formed adjacent to the second sampling gate SAM2.

First interconnection patterns M1 may be provided in the first to fifth interlayer insulating layers IL1 to IL5. Some of the first interconnection patterns M1 may be connected to the substrate 1 through the first and second contact plugs CT1 and CT2.

The first and second capacitors C1 and C2 may be disposed on the substrate 1 and in the sixth interlayer insulating layer IL6. The first and second capacitors C1 and C2 may be provided on each of the pixel regions PX, as shown in FIG. 3. The first and second capacitors C1 and C2 may overlap with the photoelectric conversion part PD in the third direction. The first and second capacitors C1 and C2 may be spaced apart from each other in the first direction D1. Each of the first and second capacitors C1 and C2 may include a plurality of electrodes, which are stacked, and at least one dielectric layer, which is interposed between each pair of the electrodes.

The first capacitor C1 may include first and second electrodes ET1 and ET2. The first electrode ET1 may include multiple first electrode layers, and the second electrode may include multiple second electrode layers, which are alternately stacked on top of each other. First dielectric layers DL1 are interposed between adjacent first electrode layers and second electrode layers, respectively. In an embodiment, the first electrode layers may correspond to odd-numbered ones of the electrode layers, which are stacked on the substrate 1. The second electrode layers may correspond to even-numbered ones of the electrode layers, which are stacked on the substrate 1. The number of electrode layers of the first and second electrodes ET1 and ET2 are not limited to those in the illustrated embodiment, and the first capacitor C1 may be provided to include more electrode layers. Some of the electrode layers in the first capacitor C1 may have a stepwise structure (e.g., an electrode layer may have portions in two different vertical levels of the first capacitor C1). As used herein, a “vertical level” refers to a region defined by a plane parallel to the first surface of the substrate that is a fixed vertical distance from the first surface of the substrate. As shown in FIG. 4, portions of the first electrode, which are located at the same vertical level, may have an opening OP. The second electrode layers may be stacked on the opening OP. A first dielectric layer DL1 may not be provided on an uppermost one of the first electrode layers, which is located at the uppermost vertical level.

The second capacitor C2 may include a third electrode ET3 and a fourth electrode ET4. The third electrode ET3 may include multiple third electrode layers and the fourth electrode ET4 may include multiple fourth electrode layers that are alternately stacked on top of each other, and second dielectric layers DL2 may be interposed between adjacent third electrode layers and fourth electrode layers, respectively. As an example, the third electrode layers may correspond to odd-numbered ones of the electrode layers, which are stacked on the substrate 1. The fourth electrode layers may correspond to even-numbered ones of the electrode layers, which are stacked on the substrate 1. Some of the electrodes in the second capacitor C2 may have a stepwise structure (e.g., an electrode layer may have portions in two different vertical levels of the second capacitor C2). As shown in FIG. 6, portions of the third electrode layers, which are located at the same vertical level, may have an opening OP. The fourth electrode layers may be stacked on the opening OP. A second dielectric layer DL2 may not be provided on an uppermost third electrode layer, which is placed at the uppermost vertical level.

Referring to FIGS. 3 to 5, the first electrode layers of the first electrode ET1 of the first capacitor C1 and the third electrode layers of the third electrode ET3 of the second capacitor C2 that are located at the same vertical level as one another may constitute a single plate (e.g., first plates PLA1), when viewed in a plan view. The first plates PLA1 may be connected to a first via VA1.

Each of the second electrode layers of the second electrode ET2 of the first capacitor C1 may constitute one of a plurality of second plates PLA2, when viewed in a plan view. Each of the fourth electrode layers of the fourth electrode ET4 of the second capacitor C2 may constitute one of a plurality of third plates PLA3, when viewed in a plan view. The second plates PLA2 may be connected to a second via VA2. The third plates PLA3 may be connected to a third via VA3.

The first plates PLA1 may be vertically overlapped with the second and third plates PLA2 and PLA3. Here, the first capacitor C1 may have a structure, in which the first and second plates PLA1 and PLA2 are alternately stacked. The second capacitor C2 may have a structure, in which the first and third plates PLA1 and PLA3 are alternately stacked. The second and third plates PLA2 and PLA3 may be spaced apart from each other in the first direction D1. An area of each of the first plates PLA1 may be larger than an area of each of the second plates PLA2 and an area of each of the third plates PLA3.

Each of the first and second capacitors C1 and C2 may be a metal-insulator-metal (MIM)-type capacitor. In an embodiment, the first electrode layers of the first electrode ET1, the second electrode layers of the second electrode ET2, the third electrode layers of the third electrode ET3, and the fourth electrode layers of the fourth electrodes ET4 may each be provided in pairs or more. The numbers of the first electrode layers, the second electrode layers, the third electrode layers, and the fourth electrode layers ET4 are not limited to those in the illustrated embodiment, and each of the first and second capacitors C1 and C2 may be provided to include more electrode layers.

The first electrodes ET1, the second electrodes ET2, the third electrodes ET3, and the fourth electrodes ET4 may be formed of or include at least one of doped polysilicon, aluminum, copper, tungsten, ruthenium, rhodium, titanium, tantalum, titanium nitride, or tantalum nitride. The first and second dielectric layers DL1 and DL2 may be formed of or include at least one of aluminum oxide, hafnium oxide, iridium oxide, or ruthenium oxide.

The first via VA1 may be disposed between the first and second capacitors C1 and C2. The first via VA1 may be disposed to penetrate through the fourth to sixth interlayer insulating layers IL4 to IL6. The first and second capacitors C1 and C2 may have a symmetric structure with respect to the first via VA1. The first via VA1 may be disposed between the first and second sampling gates SAM1 and SAM2.

The first via VA1 may be connected to at least one of the electrodes in the first capacitor C1 and at least one of the electrodes in the second capacitor C2. For example, the first via VA1 may be connected to the first electrodes ET1 in the first capacitor C1 and the third electrodes ET3 in the second capacitor C2. The first via VA1 may be spaced apart from the second electrodes ET2 in the first capacitor C1 and the fourth electrodes ET4 in the second capacitor C2.

A distance DS between the second and fourth electrodes ET2 and ET4 in the first direction D1 may be larger than 1.5 times a width VA1W of the first via VA1 in the first direction D1. An end portion of the first via VA1 may be connected to at least one of the first interconnection patterns M1. The first via VA1 may be electrically disconnected (e.g., insulated) from the substrate 1. A power supply voltage VPIX described with reference to FIG. 2 may be applied to the first via VA1. In an embodiment, a ground voltage may be applied to the first via VA1.

The first via VA1 may include a first conductive pattern FM1 and a first barrier pattern BM1 on the first conductive pattern FM1. The first barrier pattern BM1 may be provided to enclose or cover bottom and side surfaces of the first conductive pattern FM1. In an embodiment, the first conductive pattern FM1 may be formed of or include at least one metallic material (e.g., aluminum, copper, tungsten, molybdenum, or cobalt). The first barrier pattern BM1 may include a metal layer and a metal nitride layer.

As shown in FIG. 7, the second via VA2 may be arranged to penetrate through the first capacitor C1 and the fourth to sixth interlayer insulating layers IL4 to IL6. The second via VA2 may be vertically overlapped with the first capacitor C1. The second via VA2 may be connected to at least one of the electrodes of the first capacitor C1. For example, the second via VA2 may be connected to the second electrode ET2 in the first capacitor C1 (e.g., the second electrode layers). The second via VA2 may be spaced apart from the first electrode ET1 in the first capacitor C1. For example, the second via VA2 may be connected to the electrode in the first capacitor C1 that is not connected to the first via VA1.

An end portion of the second via VA2 may be connected to the first interconnection patterns M1. The second via VA2 may be electrically connected to the substrate 1 through the first interconnection patterns M1 and the first contact plug CT1. The second via VA2 may be a node-selection via.

The second via VA2 may include a second conductive pattern FM2 and a second barrier pattern BM2 on the second conductive pattern FM2. The second barrier pattern BM2 may be provided to enclose or cover bottom and side surfaces of the second conductive pattern FM2. In an embodiment, the second conductive pattern FM2 may be formed of or include at least one metallic material (e.g., aluminum, copper, tungsten, molybdenum, or cobalt). The second barrier pattern BM2 may include a metal layer and a metal nitride layer.

As shown in FIG. 8, the third via VA3 may be provided to penetrate through the second capacitor C2 and the fourth to sixth interlayer insulating layers IL4 to IL6. The third via VA3 may be vertically overlapped with the second capacitor C2. The third via VA3 may be connected to at least one of the electrodes of the second capacitor C2. For example, the third via VA3 may be connected to the fourth electrode ET4 in the second capacitor C2. The third via VA3 may be spaced apart from the third electrode ET3 in the second capacitor C2. For example, the third via VA3 may be connected to the electrode in the second capacitor C2 that is not connected to the first via VA1.

An end portion of the third via VA3 may be connected to at least one of the first interconnection patterns M1. The third via VA3 may be electrically connected to the substrate 1 through the first interconnection patterns M1 and the second contact plug CT2. In an embodiment, the third via VA3 may be a node-selection via. The second and third vias VA2 and VA3 may be used to determine where a signal value will be stored, either in the first capacitor C1 or the second capacitor C2.

The third via VA3 may include a third conductive pattern FM3 and a third barrier pattern BM3 on the third conductive pattern FM3. The third barrier pattern BM3 may be provided to enclose or cover bottom and side surfaces of the third conductive pattern FM3. In an embodiment, the third conductive pattern FM3 may be formed of or include at least one metallic material (e.g., aluminum, copper, tungsten, molybdenum, or cobalt). The third barrier pattern BM3 may include a metal layer and a metal nitride layer. Referring to FIG. 4, a width of the opening OP in the first plate PLA1 may be larger than widths of the second and third vias VA2 and VA3.

The seventh interlayer insulating layer IL7 and the eighth interlayer insulating layer IL8 may be disposed on the sixth interlayer insulating layer IL6. Second interconnection patterns M2 may be provided in the seventh interlayer insulating layer IL7 and the eighth interlayer insulating layer IL8. The second interconnection patterns M2 may be connected to the first via VA1, the second via VA2, and the third via VA3.

A fixed charge layer 42 may be disposed on a second surface 100b of the substrate 1. The fixed charge layer 42 may be formed of a metal oxide layer, whose oxygen content is lower than its stoichiometric ratio, or a metal fluoride layer, whose fluorine content ratio is lower than its stoichiometric ratio. Thus, the fixed charge layer 42 may have negative fixed charges. The fixed charge layer 42 may be formed of metal oxide or metal fluoride containing at least one metal, which is selected from the group consisting of hafnium (Hf), zirconium (Zr), aluminum (Al), tantalum (Ta), titanium (Ti), yttrium (Y), and lanthanoid. A hole accumulation phenomenon may occur near the fixed charge layer 42. Accordingly, it may be possible to effectively reduce the dark current issue and the white spot issue. In an embodiment, the fixed charge layer 42 may be formed of or include at least one of aluminum oxide or hafnium oxide.

A grid 45 may be provided on the fixed charge layer 42. In an embodiment, the grid 45 may be vertically overlapped with the isolation structure DTI in a specific region; however, considering an incident angle of light, it may not be vertically overlapped with the isolation structure DTI in other regions. The grid 45 may include a first material pattern 44 and a second material pattern 46. The first material pattern 44 may include an optically opaque material (e.g., titanium). A side surface of the second material pattern 46 may be aligned to a side surface of the first material pattern 44. The first and second material patterns 44 and 46 may be provided to prevent a crosstalk issue between adjacent ones of pixels. The second material pattern 46 may include an organic material. In an embodiment, the second material pattern 46 may be formed to have a refractive index of about 1.3 or lower.

A color filter CF may be disposed on the fixed charge layer 42. The color filter CF may be formed of or include a photoresist material containing dye or pigment. Although not shown, the color filters CF on the photoelectric conversion parts PD may be arranged to form a Bayer pattern, a 2×2 tetra pattern, a 3×3 Nona pattern, or a 4×4 hexadeca pattern. A micro lens ML may be disposed on the color filter CF.

In an image sensor according to a comparative example, vias, which are applied with the power voltage, are connected to a plurality of capacitors, respectively. Due to the presence of the vias, a facing area between electrodes stacked in the capacitors may be reduced, and this may lead to a reduction in an effective area of the capacitors. In this case, the capacitance of the capacitors may be reduced, and thus, the electrical characteristics of the image sensor may be deteriorated.

By contrast, the image sensor according to an embodiment of the inventive concept may include a plurality of capacitors and a via, which is disposed between the capacitors and is applied with a power voltage. Since the capacitors are connected to the power voltage through a common single via, a facing area between electrodes, which are stacked in each of the capacitors, may be increased. As a result, the effective area and the capacitance of the capacitor may be increased. Accordingly, it may be possible to improve the noise characteristics of the image sensor and to improve the electrical characteristics of the image sensor.

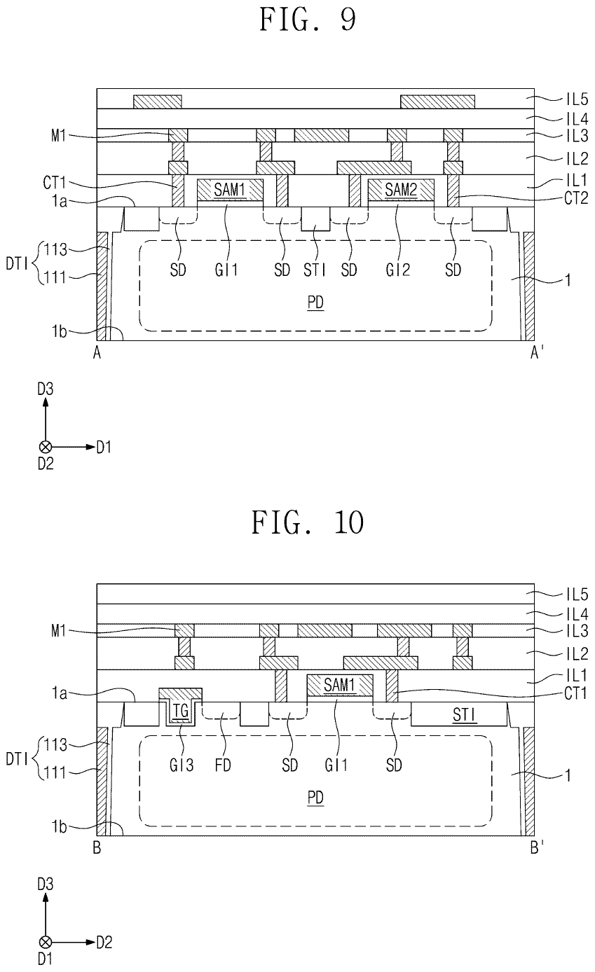

FIGS. 9, 10, 11, 12, 13, 14, 15, and 16 are sectional views illustrating a process of fabricating an image sensor according to an embodiment of the inventive concept. In detail, FIGS. 9, 11, 13, and 15 are sectional views taken along a line A-A′ of FIG. 3. FIGS. 10, 12, 14, and 16 are sectional views taken along a line B-B′ of FIG. 3.

Referring to FIGS. 9 and 10, the substrate 1 may be prepared. The substrate 1 may have the first surface 1a and the second surface 1b, which are opposite to each other. The device isolation portion STI may be formed on the first surface 1a of the substrate 1. In an embodiment, the device isolation portion STI may be formed through a shallow trench isolation (STI) process.

The isolation structure DTI may be formed to penetrate the device isolation portion STI and the substrate 1. The isolation structure DTI may include the first isolation pattern 111 and the second isolation pattern 113. The photoelectric conversion part PD and the floating diffusion region FD may be formed in the substrate 1 through an ion implantation process.

The first sampling gate SAM1, the second sampling gate SAM2, and the transfer gate TG may be formed on the first surface 1a of the substrate 1, and the first to third gate insulating layers GI to GI3 may be formed between the substrate 1 and each of the gates. The impurity regions SD may be formed in the substrate 1 and at both sides of each of the first and second sampling gates SAM1 and SAM2 through an ion implantation process.

The first interlayer insulating layer IL1 may be formed on the first surface 1a. The first and second contact plugs CT1 and CT2 may be formed to penetrate the first interlayer insulating layer IL1. Next, the second to fifth interlayer insulating layers IL2 to IL5 may be formed on the first interlayer insulating layer IL1, and the first interconnection patterns M1 may be formed in the second to fifth interlayer insulating layers IL2 to IL5.

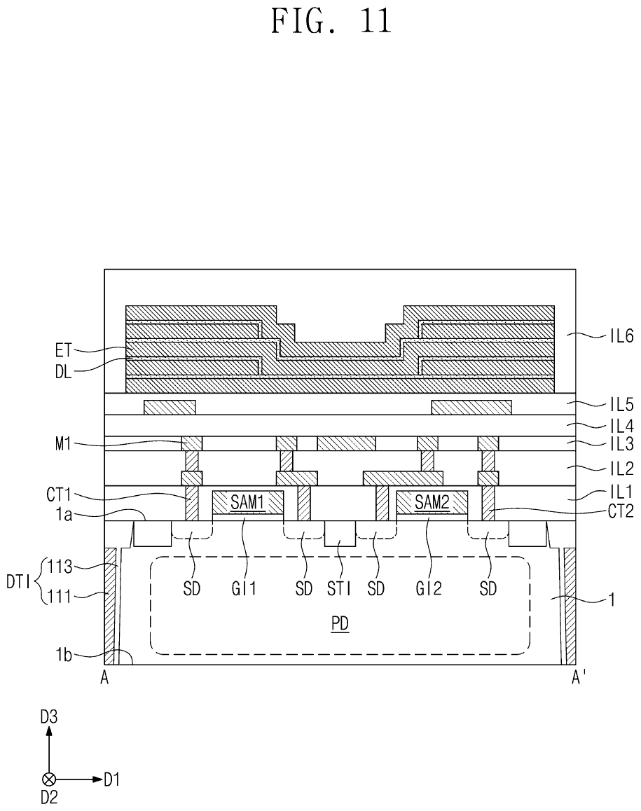

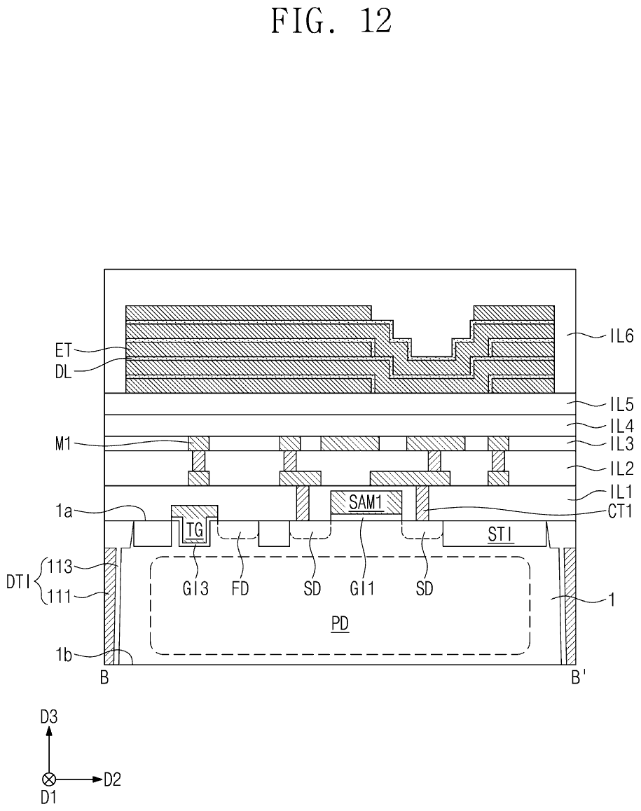

Referring to FIGS. 11 and 12, a preliminary electrode layer ET may be formed on the fifth interlayer insulating layer IL5. Next, a dielectric layer DL may be formed on the preliminary electrode ET. The process of forming the preliminary electrode layer ET and the dielectric layer DL may be repeatedly performed to obtain a plurality of preliminary electrode ET layers and dielectric layers DL. Here, at least one of the preliminary electrode layers ET may be deposited to have a stepwise structure. After the deposition, at least one of the preliminary electrode layers ET may be patterned. In an embodiment, each of the preliminary electrode layers ET at even-numbered vertical levels may be divided into a plurality of portions, which are spaced apart from each other in the first direction D1. The dielectric layer DL may not be formed on the uppermost one of the preliminary electrode layers ET. Thereafter, the sixth interlayer insulating layer IL6 may be formed to cover the preliminary electrode layers ET.

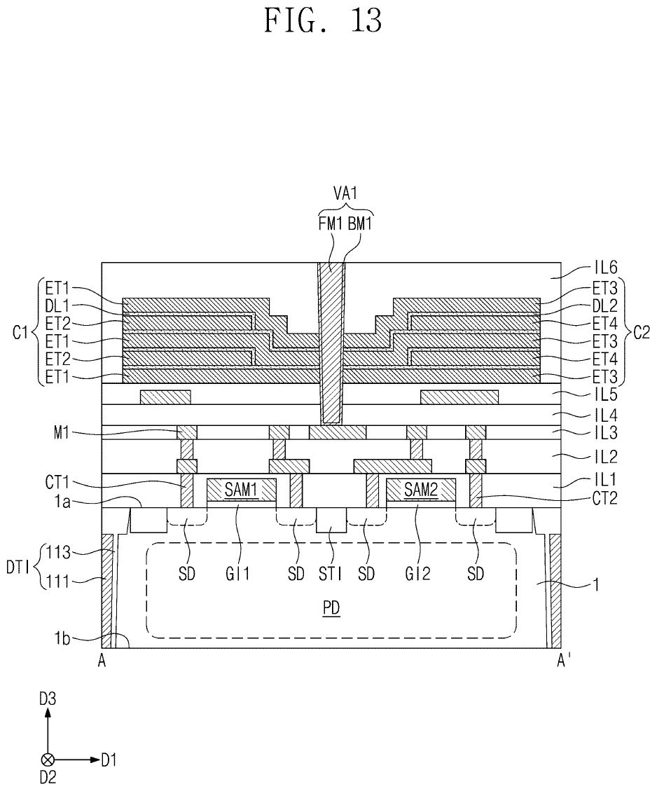

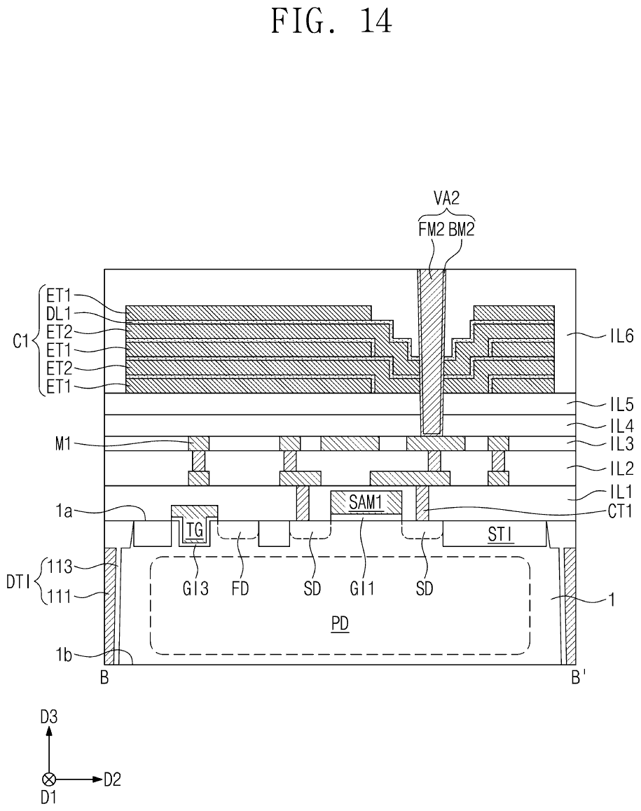

Referring to FIGS. 13 and 14, the first via VA1 may be formed to penetrate through the preliminary electrode layers ET, the dielectric layers DL, and the fourth to sixth interlayer insulating layers IL4 to IL6. The first via VA1 may include the first conductive pattern FM1 and the first barrier pattern BM1 on the first conductive pattern FM1.

Since the first via VA1 is formed to penetrate through the preliminary electrodes ET that are formed in the step of FIGS. 11 and 12, the first and second capacitors C1 and C2 may be formed from the preliminary electrode layers ET. The first and second capacitors C1 and C2 may be spaced apart from each other in the first direction D1, with the first via VA1 interposed therebetween.

The first capacitor C1 may include the first and second electrodes ET1 and ET2, which are alternately stacked on top of each other, and the first dielectric layer DL1 interposed between the first and second electrodes ET1 and ET2. The second capacitor C2 may include the third and fourth electrodes ET3 and ET4, which are alternately stacked on top of each other, and the second dielectric layer DL2 interposed between the third and fourth electrodes ET3 and ET4. Here, the first via VA1 may be connected to the first electrodes ET1 in the first capacitor C1 and the third electrodes ET3 in the second capacitor C2.

Next, the second via VA2 may be formed to penetrate through the first capacitor C1 and the fourth to sixth interlayer insulating layers IL4 to IL6. The second via VA2 may include the second conductive pattern FM2 and the second barrier pattern BM2 on the second conductive pattern FM2. The second via VA2 may be connected to the second electrode ET2 in the first capacitor C1.

Although not shown, the third via VA3 may be formed by a process that is similar to the process of forming the second via VA2. The third via VA3 may be formed to penetrate through the second capacitor C2 and the fourth to sixth interlayer insulating layers IL4 to IL6. The third via VA3 may be connected to the fourth electrode ET4 in the second capacitor C2, as shown in FIG. 8. In an embodiment, the third via VA3 may be formed in the same process as the process of forming the second via VA2 or by an additional process.

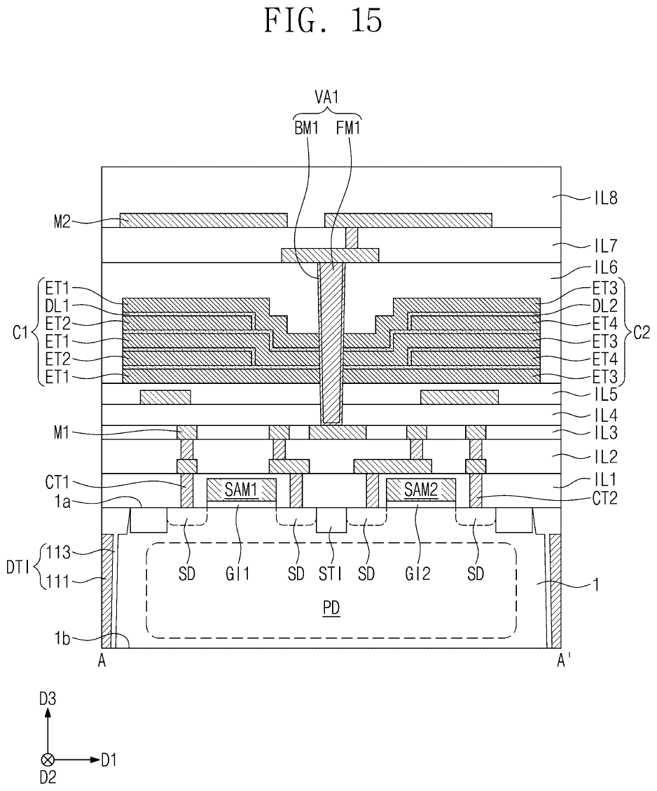

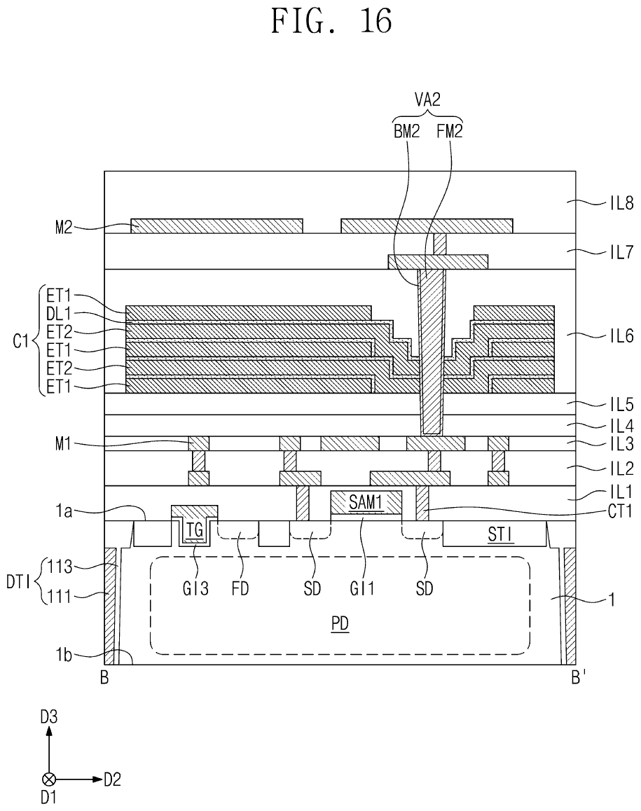

Referring to FIGS. 15 and 16, the seventh and eighth interlayer insulating layers IL7 and IL8 may be formed on the sixth interlayer insulating layer IL6, and the second interconnection patterns M2 may be formed in the seventh and eighth interlayer insulating layers IL7 and IL8. Here, some of the second interconnection patterns M2 may be connected to the first to third vias VA1 to VA3.

Next, referring to FIGS. 3 to 8, the image sensor according to an embodiment of the inventive concept may be fabricated by forming the fixed charge layer 42, the color filter CF, and the micro lens ML on the second surface 1b of the substrate 1.

According to an embodiment of the inventive concept, an image sensor may include a plurality of capacitors and a via, which is disposed between the capacitors and receives a power voltage. Here, the capacitors may be connected to the power voltage through a common single via. In this case, it may be possible to increase a facing area between electrodes, which are stacked in each of the capacitors. As a result, it may be possible to increase the effective area and the capacitance of the capacitor and to improve the noise characteristics of the capacitor, and thus, the image sensor may have improved electrical characteristics.

While example embodiments of the inventive concept have been particularly shown and described, it will be understood by one of ordinary skill in the art that variations in form and detail may be made therein without departing from the spirit and scope of the attached claims.

What is claimed is:

1. An image sensor, comprising:
a substrate including a photodiode;
a first capacitor and a second capacitor provided on the substrate and spaced apart from each other in a first direction parallel to a top surface of the substrate; and
a first via extending lengthwise in a vertical direction and disposed between the first and second capacitors,
wherein the first capacitor comprises a first electrode, a second electrode, and a first dielectric layer interposed between the first and second electrodes,
the second capacitor comprises a third electrode, a fourth electrode, and a second dielectric layer interposed between the third and fourth electrodes, and
the first via is electrically connected to the first and third electrodes.

2. The image sensor of claim 1, wherein the first via is spaced apart from the second and fourth electrodes.

3. The image sensor of claim 1, wherein a distance between the second and fourth electrodes in the first direction is larger than 1.5 times a width of the first via in the first direction.

4. The image sensor of claim 1, wherein the first and third electrodes are both located at a first vertical level, and
the second and fourth electrodes are both located at a second vertical level.

5. The image sensor of claim 1, further comprising a second via penetrating through the first capacitor,
wherein the second via is spaced apart from the first electrode and is electrically connected to the second electrode.

6. The image sensor of claim 5, further comprising a third via penetrating through the second capacitor,
wherein the third via is spaced apart from the third electrode and is electrically connected to the fourth electrode.

7. The image sensor of claim 6, further comprising:
an interlayer insulating layer disposed between the substrate and the first and second capacitors; and
a first contact plug penetrating through the interlayer insulating layer and electrically connected to the substrate,
wherein the second via is electrically connected to the substrate through the first contact plug.

8. The image sensor of claim 7, further comprising a second contact plug, which penetrates through the interlayer insulating layer and is electrically connected to the substrate,
wherein the third via is electrically connected to the substrate through the second contact plug.

9. The image sensor of claim 1, wherein the first via is configured to receive a power supply voltage.

10. The image sensor of claim 1, wherein the photodiode vertically overlaps the first and second capacitors.

11. The image sensor of claim 1, wherein the first electrode comprises a plurality of first electrode layers, the second electrode comprises a plurality of second electrode layers, the third electrode comprises a plurality of third electrode layers, and the fourth electrode comprises a plurality of fourth electrode layers, and,
the first electrode layers and the second electrode layers are alternately stacked on top of each other, and
the third electrode layers and the fourth electrode layers are alternately stacked on top of each other.

12. An image sensor, comprising:
a substrate including a photodiode;
a first capacitor and a second capacitor provided on the substrate and spaced apart from each other in a first direction parallel to a top surface of the substrate;
a first via extending lengthwise in a vertical direction and disposed between the first and second capacitors;
a second via vertically overlapping with the first capacitor; and
a third via vertically overlapping with the second capacitor,
wherein the first capacitor comprises a first stack of electrodes and dielectric layers alternately stacked with the electrodes,
the second capacitor comprises a second stack of electrodes and dielectric layers alternately stacked with the electrodes,
the first via is electrically connected to a first electrode in the first capacitor and a third electrode in the second capacitor,
the second via is electrically connected to a second electrode in the first capacitor that is not electrically connected to the first via, and
the third via is electrically connected to a fourth electrode in the second capacitor that is not electrically connected to the first via.

13. The image sensor of claim 12, further comprising a first sampling gate and a second sampling gate on the substrate,
wherein the first via is disposed between the first sampling gate and the second sampling gate.

14. The image sensor of claim 12, wherein at least one of the electrodes in the first stack of electrodes and dielectric layers has a stepwise structure that extends horizontally in two different vertical levels of the first stack of electrodes and dielectric layers.

15. The image sensor of claim 12, wherein the first and second capacitors have a symmetric structure with respect to the first via.

16. An image sensor, comprising:
a substrate comprising a photodiode and having a first surface and a second surface, which are opposite to each other in a vertical direction;
a first capacitor and a second capacitor provided on the first surface of the substrate and spaced apart from each other in a first horizontal direction;
a first via disposed between the first and second capacitors;
a second via vertically overlapping with the first capacitor; and
a third via vertically overlapping with the second capacitor,
wherein the first capacitor comprises first and second electrodes, which are stacked on top of each other in the vertical direction, and a first dielectric layer, which is interposed between the first and second electrodes,
the second capacitor comprises third and fourth electrodes, which are stacked on top of each other in the vertical direction, and a second dielectric layer interposed between the third and fourth electrodes,
the first via is electrically connected to the first and the third electrodes,
the second via is electrically connected to the second electrode,
the third via is electrically connected to the fourth electrode, and
the first and third electrodes constitute a first plate.

17. The image sensor of claim 16, wherein the second electrode constitutes a second plate,
the fourth electrode constitutes a third plate, and
the first plate vertically overlaps with the second plate and the third plate.

18. The image sensor of claim 17, wherein an area of the first plate is larger than an area of the second plate and larger than an area of the third plate.

19. The image sensor of claim 16, wherein the first to fourth electrodes each comprise a plurality of electrode layers.

20. The image sensor of claim 19, wherein the electrode layers of the first electrode are disposed at odd-numbered vertical levels in the first capacitor,
the electrode layers of the second electrode are disposed at even-numbered vertical levels in the second capacitor,
the electrode layers of the third electrode are disposed at odd-numbered vertical levels in the second capacitor, and
the electrode layers of the fourth electrodes are disposed at even-numbered vertical levels in the second capacitor.
